(19) United States
(12) Patent Application Publication
(10) Pub. No.: US 2010/0140711 A1
(43) Pub. Date: Jun. 10, 2010

(54) SEMICONDUCTOR DEVICE AND MANUFACTURING METHOD THEREOF

(75) Inventors: Norio ISHITSUKA, Kasumigaura (JP); Hiroyuki OHTA, Tsuchiura (JP); Yasuhiro KIMURA, Amagasaki (JP); Natsuo YAMAGUCHI, Tachikawa (JP); Takashi TAKEUCHI, Sagamihara (JP); Shoji YOSHIDA, Akishima (JP)

Correspondence Address: BRUNDIDGE & STANGER, P.C., 2318 MILL ROAD, SUITE 1020, ALEXANDRIA, VA, 22314, US

(73) Assignee: RENESAS TECHNOLOGY CORP., Tokyo (JP)

(21) Appl. No.: 12/628,364

(22) Filed: Dec. 1, 2009

(30) Foreign Application Priority Data
Dec. 4, 2008 (JP) 2008-309727

(51) Int. Cl. H01L 27/12; H01L 21/86

(52) U.S. Cl. 257/351; 438/154; 257/E27.112; 257/E21.704

(57) ABSTRACT

Generation of dislocation and increase of diffusion resistance at edge portions of source/drain regions in a CMIS are prevented. When source/drain regions in a CMIS are formed, argon is implanted to a P-well layer as a dislocation-suppressing element and nitrogen is implanted to an N-well layer as a dislocation-suppressing element before an ion implantation of impurities to a silicon substrate. In this manner, by separately implanting dislocation-suppressing elements suitable for each of the P-well layer and the N-well layer as well as suppressing the generation of dislocation, increase of diffusion resistance can be suppressed, yield can be improved, and the reliability of devices can be increased.

### CROSS-REFERENCE TO RELATED APPLICATION

The present application claims priority from Japanese Patent Application No. JP 2008-309727 filed on Dec. 4, 2008, the content of which is hereby incorporated by reference into this application.

### TECHNICAL FIELD OF THE INVENTION

The present invention relates to a semiconductor device and a manufacturing method of the same. More particularly, the present invention relates to a technique effectively applied to a semiconductor device having a CMIS structure and a manufacturing method of the same.

### BACKGROUND OF THE INVENTION

Impurities such as As (arsenic), P (phosphorus), or B (boron) (BF₂) are implanted with a high dose to source and drain regions to be gate end portions of a MIS transistor (hereinafter, simply called MIS). Since the gate end portion is a portion to which stress is concentrated, dislocation is caused in a vicinity of the gate end portion often. Since the cause of dislocation becomes a source of leakage current, dislocation causes a deterioration of electrical property of the transistor.

As a method of preventing the dislocation, Japanese Patent Application Laid-Open Publication No. H04-212418 (Patent Document 1) discloses that inert ions such as argon or nitrogen are implanted in addition to As, P, or B.

### SUMMARY OF THE INVENTION

As disclosed in Patent Document 1, through experiments by the inventors, it has been found out that, when the same type of element is implanted to an N-type MIS (hereinafter, simply called NMIS) and a P-type MIS (hereinafter, simply called PMIS), a diffusion resistance of the implanted region in either NMIS or PMIS is large. For example, when nitrogen of an amount of suppressing the dislocation is implanted to source and drain regions of the NMIS and PMIS, the diffusion resistance of the PMIS significantly increases. On the other hand, when argon of an amount of suppressing the dislocation is implanted to source and drain regions of the NMIS and PMIS, the diffusion resistance of the NMIS significantly increases. The inventors have found out that, since decreases of transistor current and/or switching speed are caused when the diffusion resistance increases, it is required to select a suitable impurity capable of suppressing the dislocation and reducing the diffusion resistance for the NMIS and PMIS.

A preferred aim of the present invention is to provide a technique of manufacturing a semiconductor device in which defects and dislocations caused in source and drain regions on a substrate are suppressed, the increase of diffusion resistance as described above is prevented, and further, good performance is provided.

The above and other objects and novel characteristics of the present invention will be apparent from the description of the present specification and the accompanying drawings.

The typical ones of the inventions disclosed in the present application will be briefly described as follows.

A manufacturing method of a semiconductor device according to one of the inventions of the present application includes the following steps of:

(a) forming a gate insulating film on a main surface of a semiconductor substrate;

(b) forming each of a first gate electrode of an N-type MIS transistor and a second gate electrode of a P-type MIS transistor on the gate insulating film;

(c) after the step (b), forming a low-doped N-type layer on the semiconductor substrate in a vicinity of the first gate electrode by implanting an N-type impurity to the semiconductor substrate in a region where the N-type MIS transistor is formed with using the first gate electrode as a mask and forming a low-doped P-type layer on the semiconductor substrate in a vicinity of the second gate electrode by implanting a P-type impurity to the semiconductor substrate in a region where the P-type MIS transistor is formed with using the second gate electrode as a mask;

(d) after the step (c), forming an insulating film on side surfaces of each of the first and second gate electrodes;

(e) forming source and drain regions of the N-type MIS transistor on the semiconductor substrate in a vicinity of the first gate electrode by implanting an N-type impurity and nitrogen to the semiconductor substrate in the region where the N-type MIS transistor is formed with using the first gate electrode and the insulating film as a mask; and

(f) forming source and drain regions of the P-type MIS transistor on the semiconductor substrate in a vicinity of the second gate electrode by implanting a P-type impurity and argon to the semiconductor substrate in the region where the P-type MIS transistor is formed with using the second gate electrode and the insulating film as a mask.

The effects obtained by typical aspects of the present invention disclosed in the present application will be briefly described below.

Since generation of dislocations can be prevented without increasing the diffusion resistance in source and drain regions in a CMIS, a yield can be improved and a reliability of a device can be increased.

### BRIEF DESCRIPTIONS OF THE DRAWINGS

FIG. 1 is a cross-sectional view of a principal part describing a manufacturing method of a CMIS included in a semiconductor device according to an embodiment of the present invention;

FIG. 2 is a cross-sectional view of a principal part in a manufacturing step of the semiconductor device continued from FIG. 1;

FIG. 3 is a cross-sectional view of a principal part in a manufacturing step of the semiconductor device continued from FIG. 2;

FIG. 4 is a cross-sectional view of a principal part in a manufacturing step of the semiconductor device continued from FIG. 3;

FIG. 5 is a cross-sectional view of a principal part in a manufacturing step of the semiconductor device continued from FIG. 4;

FIG. 6 is a cross-sectional view of a principal part in a manufacturing step of the semiconductor device continued from FIG. 5;

FIG. 7 is a cross-sectional view of a principal part schematically illustrating a generating mechanism of a micro defect (dislocation) crossing a P/N junction;

FIG. 8 is a cross-sectional view of a principal part illustrating EOR defects caused upon an activation annealing after an impurity-implantation to source and drain regions;

FIG. 9 is a graph illustrating a change of diffusion resistance when nitrogen or argon is implanted to an As-implanting region;

FIG. 10 is a graph illustrating a change of diffusion resistance when nitrogen or argon is implanted to a BF₂-implanting region;

FIG. 11 is a graph illustrating a change of diffusion resistance when nitrogen or argon is implanted to an As-implanting region;

FIG. 12 is a graph illustrating change of diffusion resistance when nitrogen or argon is implanted to a region where BF₂ is implanted;

FIG. 13 is a cross-sectional view of a principal part describing a manufacturing method of a CMIS included in a semiconductor device according to another embodiment of the present invention;

FIG. 14 is a cross-sectional view of a principal part of the CMIS included in the semiconductor device according to the another embodiment of the present invention;

FIG. 15 is a cross-sectional view of a principal part describing a manufacturing method of a CMIS included in a semiconductor device to which the present invention is applied; and

FIG. 16 is a cross-sectional view of a principal part of a CMIS included in a semiconductor device to which the present invention is applied.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle. Also, when “comprising A”, “formed of A”, or “formed by A” is described in components of examples or the like, it goes without saying that other components are not eliminated unless otherwise specified to be only the component.

Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. The same goes for the numerical value and the range described above.

In addition, when materials and others are mentioned, specified one is a main material unless otherwise stated not to be so or it is principally or apparently not so, and subsidiary components, additives, additional components, and others are not eliminated. For example, a silicon material includes not only pure silicon but also binary or ternary alloy (for example, SiGe) having additive impurities and silicon as a main component or others unless otherwise stated.

Also, components having the same function are denoted by the same reference symbols throughout the drawings for describing the embodiments, and the repetitive description thereof is omitted.

Further, in some drawings used in the following embodiments, hatching is partially used even in a plan view so as to make the drawings easy to see.

Hereinafter, embodiments of the present invention will be described based on the drawings.

### First Embodiment

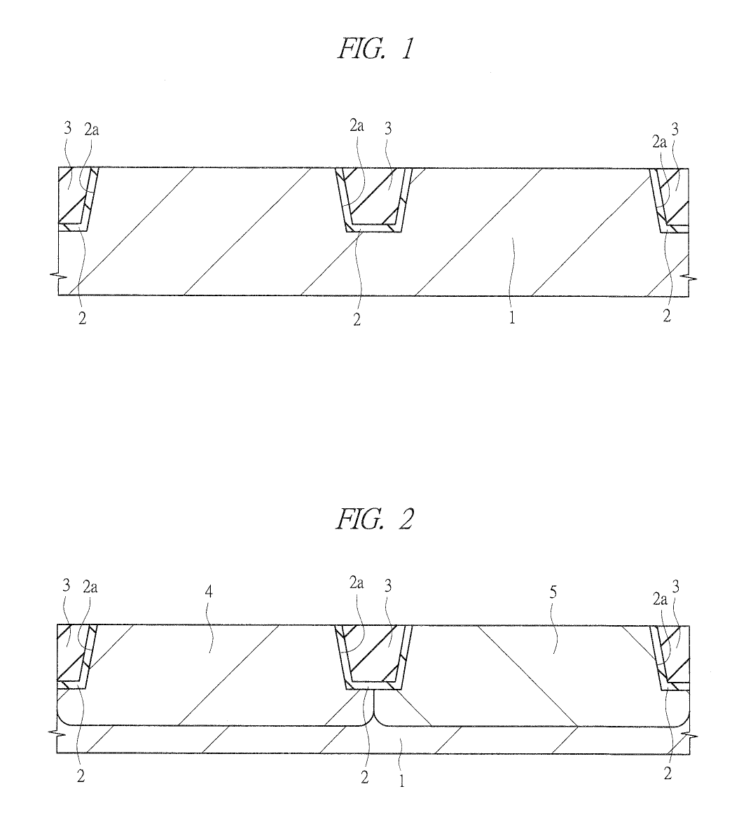

The present embodiment is applied to a manufacturing method of a CMIS, and will be described with reference to FIGS. 1 to 12.

First, as illustrated in FIG. 1, shallow trenches 2a are formed in a main surface of a silicon substrate 1, and an inside of the shallow trench 2a is thermally oxidized at temperature of about 1000° C. to form a thermal oxide film 2 having a thickness of 5 to 20 nm. And then, a buried oxide film 3 is deposited inside the shallow trench 2a by a CVD method or a sputtering method, and then, annealing is performed for one to two hours at 1000 to 1150° C. under a diluted oxidizing atmosphere or a nitrogen atmosphere to densify the buried oxide film 3 aiming at reducing its voids. Further, excessive buried oxide film 3 on the silicon substrate 1 is removed to be flattened by CMP or etch-back, so that a device isolation structure is formed.

Next, as illustrated in FIG. 2, a surface of the silicon substrate 1 is thermally processed at 900° C. under an oxidizing atmosphere to form a thermal oxide film (not illustrated) having a thickness of about 10 nm, and phosphorous which is an N-type impurity is ion-implanted to a PMIS region and boron which is a P-type impurity is ion-implanted to an NMIS region in the silicon substrate 1 with a dose of about 1×10¹³ (ions/cm²) with using the thermal oxide film as a buffer layer, so that a P-well layer 4 and an N-well layer 5 are formed. And then, the thermal oxide film is removed by diluted HF.

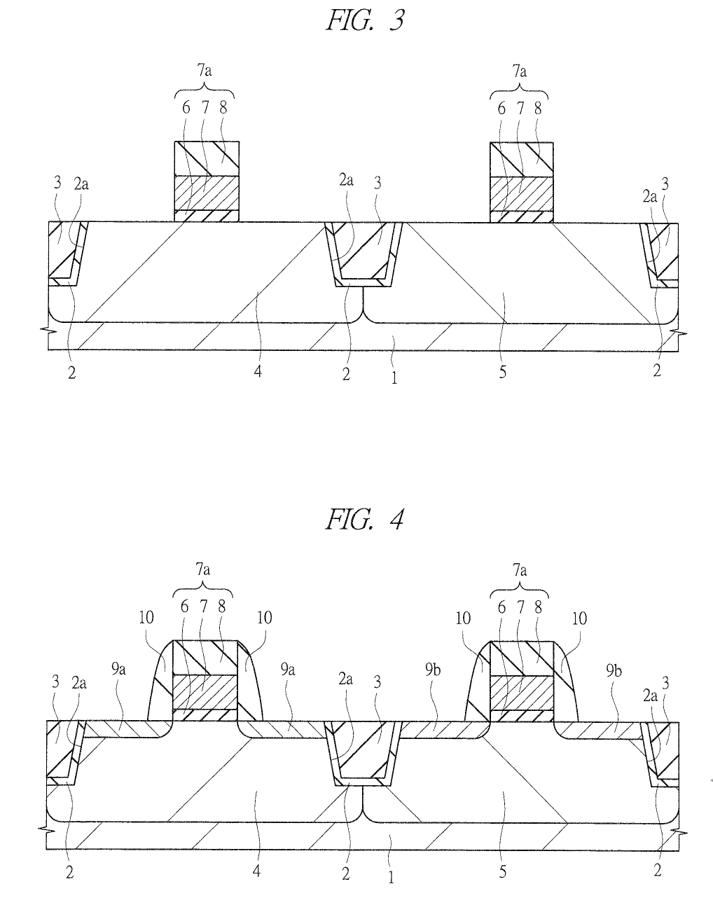

Next, as illustrated in FIG. 3, a gate oxide film 6, a polycrystalline silicon film 7, a first insulating film 8 are sequentially deposited, and then, they are patterned by photolithography technique to form a gate electrode 7a.

Next, as illustrated in FIG. 4, a thermal oxide film (not illustrated) having a thickness of 3 to 10 nm is formed on the surface of the silicon substrate 1 by a thermal treatment at 900° C. in an oxidizing atmosphere, and boron is ion-implanted to the N-well layer 5 and arsenic is ion-implanted to the P-well layer 4 with a dose of about 1×10¹³ (ions/cm²) with using the thermal oxide film as a buffer layer, so that low-doped layers 9a and 9b are formed. Note that, when the impurity is ion-implanted to the N-well layer 5, the P-well layer 4 side is covered by a photoresist (not illustrated) so as not to be ion-implanted with the impurity. Similarly, when the impurity is ion-implanted to the P-well layer 4, the N-well layer 5 side is covered by a photoresist (not illustrated) so as not to be ion-implanted with the impurity.

Next, a second insulating film 2 made of silicon oxide is deposited on the main surface of the silicon substrate 1, and then, the thermal oxide film (buffer layer) and the second insulating film 2 are remained on only sidewalls of the gate electrode 7a by anisotropic dry etching to form sidewalls 10, so that an LDD structure is formed.

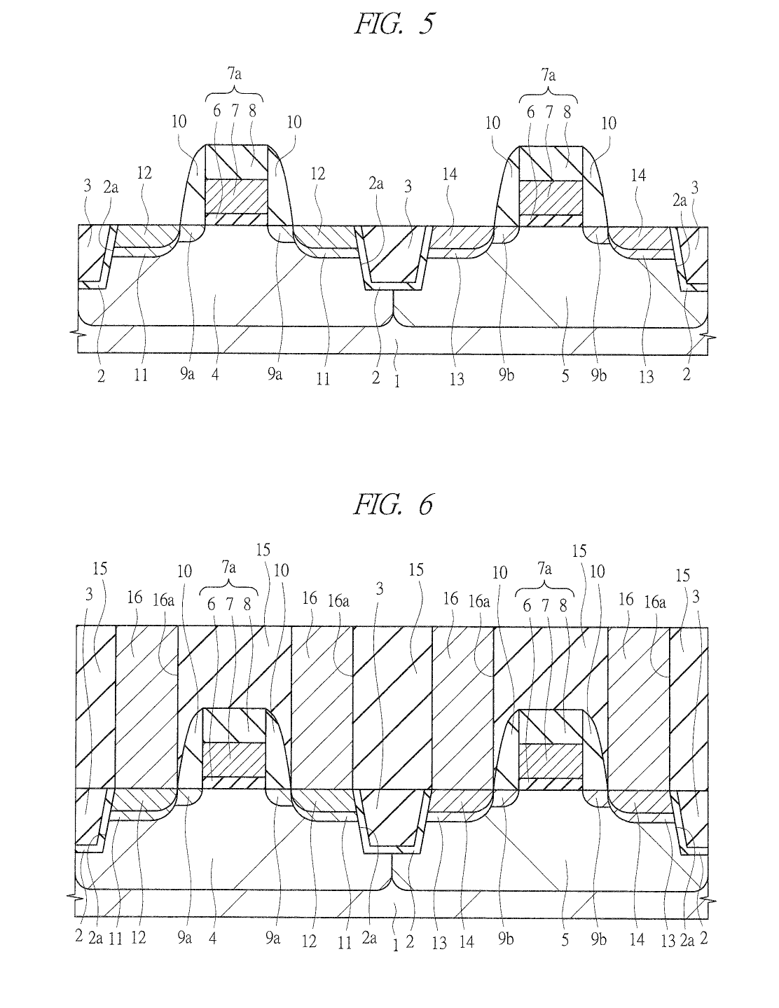

Next, as illustrated in FIG. 5, nitrogen molecular ions are implanted to the P-well layer 4 with a dose of about 1×10¹⁵ to 3×10¹⁵ (ions/cm²) at 20 to 40 keV to form nitrogen-implanted regions 11, and further, arsenic ions are implanted to the P-well layer 4 with a dose of about 5×10¹⁴ to 3×10¹⁵ (ions/cm²) at 50 keV to form source/drain regions 12. And then, argon ions are implanted to the N-well layer 5 with a dose of about 0.5×10¹⁵ to 1.5×10¹⁵ (ions/cm²) at 20 to 40 keV to form argon-implanted regions 13, and further, boron ions are implanted to the N-well layer 5 with a dose of about 5×10¹⁴ to 3×10¹⁵ (ions/cm²) at 30 key to form source/drain regions 14. And then, activation annealing at about 1000° C. is performed. Note that, when argon ions are ion-implanted to the N-well layer 5, the P-well layer 4 side is covered by a photoresist (not illustrated) so as not to be ion-implanted with argon ions. Similarly, when nitrogen ions are ion-implanted to the P-well layer 4, the N-well layer 5 side is covered by a photoresist (not illustrated) so as not to be ion-implanted with nitrogen ions.

Next, as illustrated in FIG. 6, a silicon oxide film 15 is deposited and then patterned by photolithography technique to form a tungsten film 16 to be an electrode plug inside each of contact holes 16a for drawing the electrodes out from the source/drain regions 12, and wirings (not illustrated) are formed on the silicon oxide film 15 and the tungsten film 16, so that the CMIS is completed.

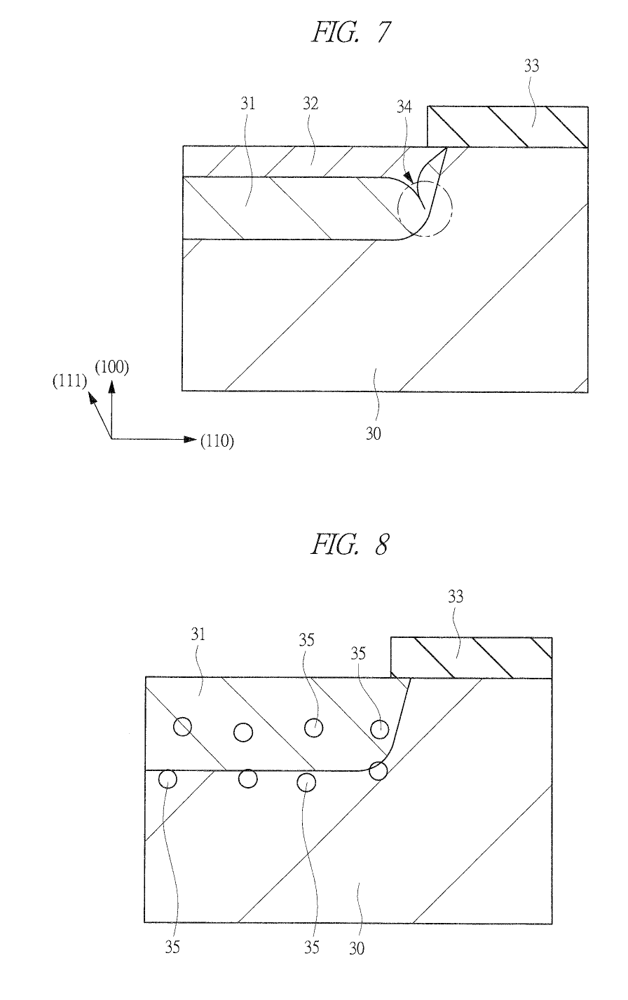

Next, effects of the present embodiment will be described. First, the inventors have manufactured a sample as illustrated in FIG. 7 for studying a generating mechanism of dislocation. A mask film 33 patterned in stripe shape is formed on a main surface of a silicon substrate 30, and further, As or BF₂ is implanted to an exposed portion of the silicon substrate 30 with the same condition described above. That is, nitrogen molecular ions are implanted to the silicon substrate 30 with a dose of about 1×10¹⁵ to 3×10¹⁵ (ions/cm²) at 20 to 40 keV, and further, arsenic ions are implanted to the silicon substrate 30 with a dose of about 5×10¹⁴ to 3×10¹⁵ (ions/cm²) at 50 keV. Also, in another sample, argon ions are implanted to the silicon substrate 30 with a dose of about 0.5×10¹⁵ to 1.5×10¹⁵ (ions/cm²) at 20 to 40 keV, and further, boron ions are ion-implanted to the silicon substrate 30 with a dose of about 5×10¹⁴ to 3×10¹⁵ (ions/cm²) at 30 keV.

After annealing the above silicon substrate 30, a TEM (transmission electron microscope) observation was performed to the samples, and as a result, it was found out as follows regarding the dislocation. First, micro defects called SPE (solid phase epitaxial) defects are caused at an interface between an amorphous region 32 and a re-crystallized region 31 in a vicinity of an end portion of the mask film 33, and then, the SPE defects 34 are grown to large defects (dislocation) crossing a P/N junction by stress of the mask film 33.

Here, results of a consideration of the generating mechanism of the micro defects will be described with reference to FIG. 7. The silicon substrate 30 is amorphized upon the impurity implantation to the source/drain region, and then, the amorphous region 32 is re-crystallized upon the activation annealing, and at this time, the amorphous region 32 is re-crystallized from a portion of amorphous/single-crystal Si. Since the re-crystallization speed depends on the surface orientation, growing interfaces are hit to each other, so that the SPE defects 34 are caused at the interface. The re-crystallization speed becomes faster in an order of (111)<(110)<(100) orientation, and more particularly, the re-crystallization speed of (111) orientation is extremely slower than those of the other orientations. Therefore, the SPE defects 34 are generated in a direction of the (111) orientation.

Also, as illustrated in FIG. 8, the silicon substrate 30 is amorphized upon the impurity implantation to the source/drain region, and then, defects called EOR (end of range) defects are generated upon the activation annealing in vicinities of a highest-doped portion (Projected Range) of impurities such as As or BF₂ and the amorphous/single-crystal Si portion, and a dislocation is caused from the EOR defects 35 generated in the vicinity of the end portion of the mask film 33. From these results, it has been found out that it is important to suppress the SPE defects and the EOR defects for suppressing the dislocation.

Further, in a prior art disclosed in Patent Document 1, the same experiment as described above was performed for finding a reason of suppressing the dislocation when nitrogen or argon is implanted, and as a result, it has been found out, from the result of a TEM observation, that the suppression is achieved as the SPE defects and the EOR defects to be the starting points of the dislocation disappear.

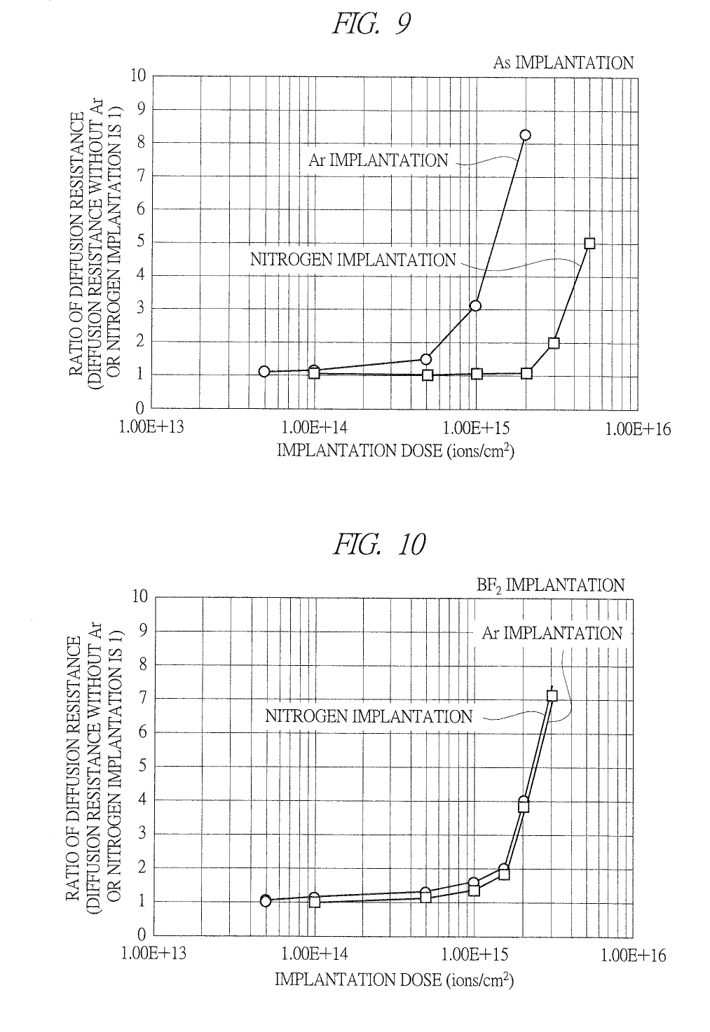

It has been found out that, when nitrogen or argon is implanted to the source/drain region, the EOR defects disappear to suppress the dislocation. However, if side effects are caused by the present method, the method cannot be applied to products or others. Since materials which are essentially and electrically unnecessary are implanted to the source/drain region in the present method, a change of film property of the implanted region is considered. A change of diffusion resistance is considered by the change of film property. Decreases of transistor current and/or switching speed are caused by an increase of the diffusion resistance. Here, FIGS. 9 and 10 illustrate the studied results of the change of diffusion resistance when nitrogen or argon is implanted. FIG. 9 illustrates a case of implanting nitrogen or argon to an As-implanted region, and FIG. 10 illustrates a case of implanting nitrogen or argon to a BF₂-implanted region, and the both implantations are performed after activation annealing. Both of FIGS. 9 and 10 illustrate results such that the diffusion resistance increases as a dose of nitrogen or argon is increased. However, when As is implanted, a dose of starting the increase of diffusion resistance differs depending on implanted species, and it was confirmed that the increase of diffusion resistance starts from a low dose when argon is implanted. When BF₂ is implanted, dependencies of the increases of diffusion resistances in nitrogen and argon are hardly different from each other.

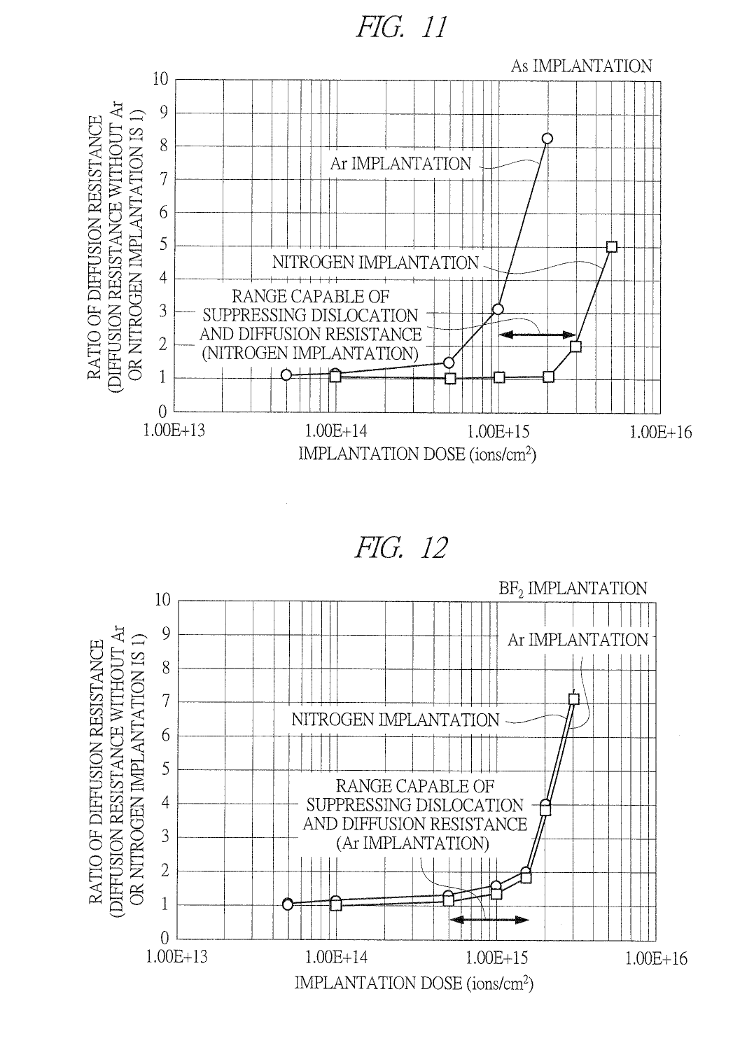

When the diffusion resistance increases to about 1.5 to 2 times its initial value, the diffusion resistance has an influence, and therefore, an allowable implantation dose when argon is implanted to the As-implanted region is 6×10¹⁴ (ions/cm²) or lower, and an allowable implantation dose when nitrogen is implanted to the As-implanted region is 3×10¹⁵ (ions/cm²) or lower as illustrated in FIG. 11. Also, as illustrated in FIG. 12, an allowable implantation dose when argon or nitrogen is implanted to the BF₂-implanted region is about 1.5×10¹⁵ (ions/cm²) or lower.

Meanwhile, it was obtained from experiments that doses of argon and nitrogen which can suppress the dislocation are 1×10¹⁵ (ions/cm²) or higher when implanting As, and, those of argon and nitrogen are 5×10¹⁴ (ions/cm²) and 1.5×10¹⁵ (ions/cm²) when implanting BF₂, respectively.

As a result, in conditions capable of suppressing the dislocation as well as suppressing the diffusion resistance when As is implanted as illustrated in FIG. 11, the nitrogen implantation dose is in a range of 1×10¹⁵ to 3×10¹⁵ (ions/cm²) and the argon implantation dose does not have a particular range. In addition, when BF₂ is implanted as illustrated in FIG. 12, the nitrogen implantation dose does not have a particular range and the argon implantation dose is in a range of 5×10¹⁴ to 1.5×10¹⁵ (ions/cm²).

That is, as to conditions capable of suppressing the dislocation as well as suppressing the diffusion resistance, it is clear that implantation of nitrogen is important in the NMIS and implantation of argon is important in the PMIS.

For suppressing the dislocation, it is important to eliminate the EOR defects and the SPE defects by the implantation of nitrogen or argon. Since the EOR defects and the SPE defects affecting the dislocation are formed at the same position at a highest-doped depth RP1 (or a Projected Range RP1) of impurities or deeper, a highest-doped depth RP2 (or a Projected Range RP2) of nitrogen or argon is preferable to be deeper than or equal to the RP1 of impurities.

### Second Embodiment

In recent years, efforts to improve electric properties have been made by depositing a layer including SiGe on a semiconductor substrate such as a strained Si substrate and forming a Si epitaxial layer on the layer to give a strain caused from SiGe to the Si epitaxial layer. This is because the strained Si has a high electron mobility, so that the operation speed of a device such as an LSI can be improved. In the present embodiment, a CMIS having a SiGe layer will be described.

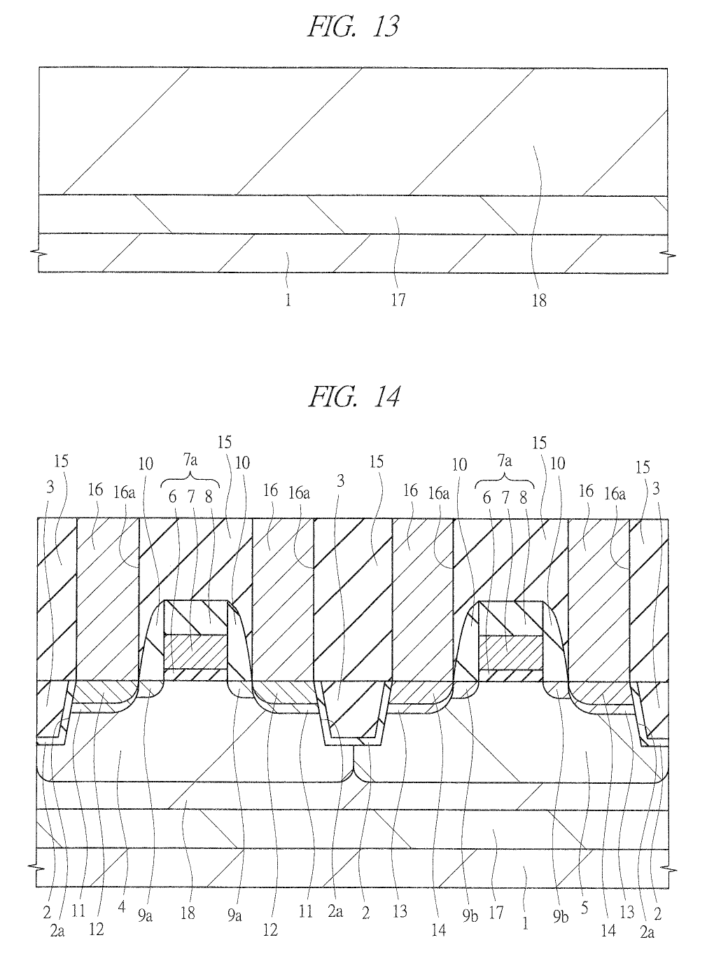

First, as illustrated in FIG. 13, a SiGe layer 17 is formed on a silicon substrate 1 by an IBS (ion beam sputtering) method, and a silicon layer 18 is formed on the SiGe layer 17 by epitaxial growth.

Next, while a device isolation structure is formed in the silicon layer 18, processes after this formation are performed similarly to those of the first embodiment.

That is, first, the device isolation structure formed of a thermal oxide film 2 and a buried oxide film 3 is formed in the silicon layer 18, and a P-well layer 4 and an N-well layer are formed therein by ion implantation, and then, a gate electrode 7a is formed. And then, boron is implanted to a surface of the N-well layer 5 region with a dose of about 1×10¹³ (ions/cm²) and arsenic is implanted to a surface of the P-well layer 4 with a dose of about 1×10¹³ (ions/cm²), so that low-doped layers 9a and 9b are formed. Note that, when impurities are ion-implanted to the N-well layer 5, the P-well layer 4 side is covered by a photoresist (not illustrated) so as not to be implanted with impurities. Similarly, when impurities are ion-implanted to the P-well layer 4, the N-well layer 5 side is covered by a photoresist (not illustrated) so as not to be implanted with impurities.

Next, sidewalls 10 are formed on side surfaces of the gate electrode 7a, and nitrogen molecular ions are implanted to the P-well layer 4 at 20 to 40 keV with a dose of 1×10¹⁵ to 3×10¹⁵ (ions/cm²) to form nitrogen-implanted regions 11, and further, arsenic ions are implanted to the P-well layer 4 at about 50 keV with a dose of 5×10¹⁴ to 3×10¹⁵ (ions/cm²) to form source/drain regions 12 in the P-well layer 4. And then, argon ions are implanted to the N-well layer 5 at 20 to 40 keV with a dose of 0.5×10¹⁵ to 1.5×10¹⁵ (ions/cm²) to form argon-implanted regions 13 in the N-well layer 5, and further, boron ions are implanted to the N-well layer 5 at about 30 keV with a dose of 5×10¹⁴ to 3×10¹⁵ (ions/cm²) to form source/drain regions 14 in the N-well layer 5. Note that, when argon ions are implanted to the N-well layer 5, the P-well layer 4 side is covered by a photoresist (not illustrated) so as not to be implanted with the argon ions. Similarly, when nitrogen ions are implanted to the P-well layer 4, the N-well layer 5 side is covered by a photoresist (not illustrated) so as not to be implanted with the nitrogen ions.

And then, a silicon oxide film 15 is deposited and patterned by photolithography technique to form a tungsten film 16 to be an electrode plug in each of contact holes 16a, and a wiring (not illustrated) is formed on the silicon oxide film 15 and the tungsten film 16, so that the OMIS illustrated in FIG. 14 is completed.

As described above, by implanting nitrogen to the NMIS and implanting argon to the PMIS, the dislocation in the device can be suppressed and the diffusion resistance can be suppressed.

Here, FIG. 14 is a cross-sectional structure diagram when the device is formed with using the semiconductor substrate including the SiGe layer 17 of FIG. 13. Since a lattice constant of SiGe is larger than that of silicon, a tensile strain is applied to the silicon layer 18. Therefore, stress from SiGe has been already caused in the source/drain region 14 since prior to the device formation, and this is a state in which the dislocation is easily caused. Therefore, the present invention is particularly effective for the cMIS device using strained Si or others.

In the foregoing, the invention made by the inventors of the present invention has been concretely described based on the embodiments. However, it is needless to say that the present invention is not limited to the foregoing embodiments and various modifications and alterations can be made within the scope of the present invention.

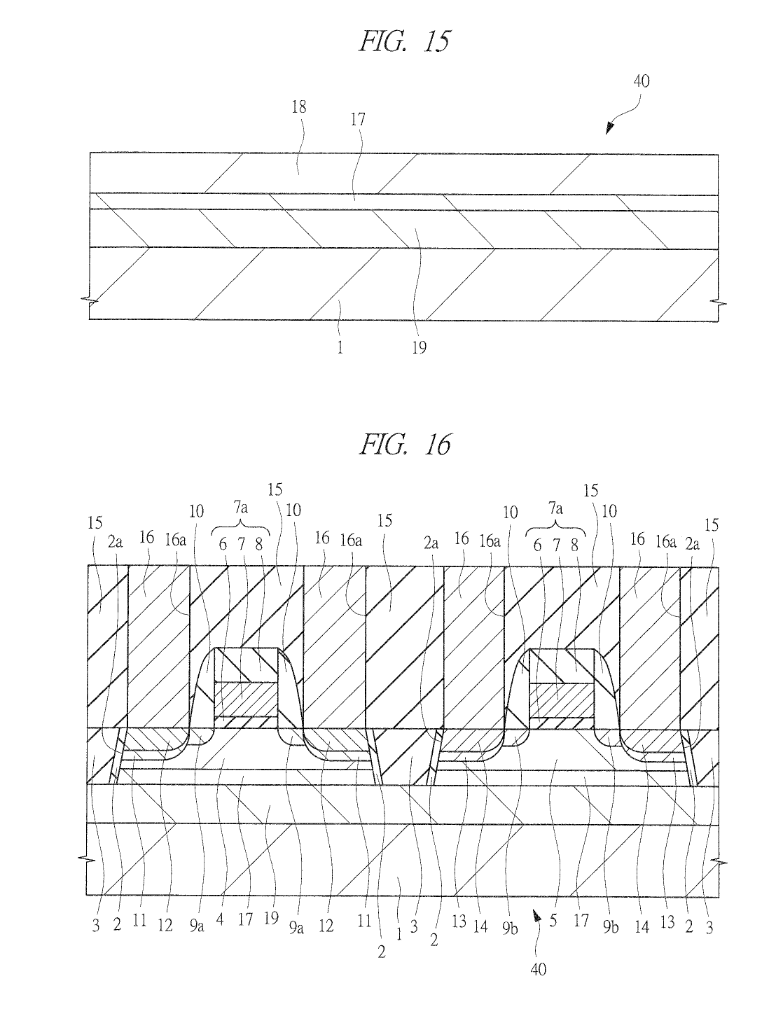

For example, FIG. 16 is a cross-sectional structure diagram when the device is formed with using a SiGe substrate 40 of FIG. 15 different from that of FIG. 13 of the second embodiment. The SiGe substrate 40 of FIG. 15 is configured with forming a SiGe layer 17 on an SOI (silicon on insulator) substrate in which a BOX (buried oxide) film 19, the SiGe layer 17, and a silicon layer 18 are formed on a silicon substrate 1. To the silicon layer 18 of FIG. 15, the same tensile strain with that of the silicon layer 18 of FIG. 13 of the second embodiment has been applied since prior to the element formation.

Here, the SOI substrate has functions of reducing a parasitic capacitance and improving the switching speed of the transistor, and is generally formed by a SIMOX (silicon implanted oxide) method or a bonding method.

In the CMIS illustrated in FIG. 16, the stress has been applied to source/drain regions 14 since prior to the device formation similar to the CMIS illustrated in FIG. 14 according to the second embodiment. Therefore, the present invention is particularly effective for the CMIS illustrated in FIG. 16. That is, the present invention is particularly effective when processes and structures causing stresses to source/drain regions are employed.

A manufacturing method of a semiconductor device of the present invention is widely used for manufacture of a semiconductor device having a CMIS structure.

What is claimed is:

1. A semiconductor device comprising: a semiconductor substrate; and an N-type MIS transistor and a P-type MIS transistor formed on a main surface of the semiconductor substrate,
each of the N-type MIS transistor and the P-type MIS transistor having source/drain regions, wherein
N (nitrogen) is contained in the source/drain regions of the N-type MIS transistor and Ar (argon) is contained in the source/drain regions of the P-type MIS transistor, respectively.

2. The semiconductor device according to claim 1, wherein
a highest-doped depth of the nitrogen contained in the source/drain regions of the N-type MIS transistor is deeper than or equal to that of an N-type impurity introduced in the source/drain regions of the N-type MIS transistor, and a highest-doped depth of the argon contained in the source/drain regions of the P-type MIS transistor is deeper than or equal to that of a P-type impurity introduced in the source/drain regions of the P-type MIS transistor.

3. The semiconductor device according to claim 1, wherein
an insulating film is deposited on the N-type and P-type MIS transistors, and an electrode plug is formed inside a contact hole formed in the insulating film, the electrode plugs being electrically connected to gate, source, and drain regions of the N-type and P-type MIS transistors.

4. The semiconductor device according to claim 1, wherein
a SiGe (silicon germanium) layer is formed on the main surface of the semiconductor substrate, an epitaxial layer containing Si (silicon) is formed on the SiGe layer, and the N-type and P-type MIS transistors are formed on the epitaxial layer.

5. The semiconductor device according to claim 1, wherein
an SOI (silicon-on-insulator) structure is formed to the main surface of the semiconductor substrate.

6. A manufacturing method of a semiconductor device comprising the steps of:
(a) forming a gate insulating film on a main surface of a semiconductor substrate;
(b) forming a first gate electrode of an N-type MIS transistor and a second gate electrode of a P-type MIS transistor on the gate insulating film;
(c) after the step (b), forming an N-type low-doped layer in the semiconductor substrate in a vicinity of the first gate electrode by implanting an N-type impurity to the semiconductor substrate in a region where the N-type MIS transistor is formed with using the first gate electrode as a mask, and forming a P-type low-doped layer in the semiconductor substrate in a vicinity of the second gate electrode by implanting a P-type impurity to the semiconductor substrate in a region where the P-type MIS transistor is formed with using the second gate electrode as a mask;
(d) after the step (c), forming an insulating film on side surfaces of each of the first and second gate electrodes;
(e) forming source/drain regions of the N-type MIS transistor in the semiconductor substrate in a vicinity of the first gate electrode by implanting an N-type impurity and N (nitrogen) to the semiconductor substrate in the region where the N-type MIS transistor is formed with using the first gate electrode and the insulating film as a mask; and
(f) forming source/drain regions of the P-type MIS transistor in the semiconductor substrate in a vicinity of the second gate electrode by implanting a P-type impurity and Ar (argon) to the semiconductor substrate in the region where the P-type MIS transistor is formed with using the second gate electrode and the insulating film as a mask.

7. The manufacturing method of a semiconductor device according to claim 6, wherein,
when nitrogen and the N-type impurity are implanted to the region where the N-type MIS transistor is formed of the semiconductor substrate with using the insulating film as a mask, a highest-doped depth of implanting nitrogen is deeper than or equal to that of implanting the N-type impurity, and,
when argon and the P-type impurity are implanted to the region where the P-type MIS transistor is formed of the semiconductor substrate with using the insulating film as a mask, a highest-doped depth of implanting argon is deeper than or equal to that of implanting the P-type impurity.

8. The manufacturing method of a semiconductor device according to claim 6, wherein
a SiGe (silicon germanium) layer is formed on the main surface of the semiconductor substrate, an epitaxial layer containing Si (silicon) is formed on the SiGe layer, and the N-type and P-type MIS transistors are formed on the epitaxial layer.

9. The manufacturing method of a semiconductor device according to claim 6, wherein
an insulating film is deposited on the N-type and P-type MIS transistors, and an electrode plug is formed inside a contact hole formed in the insulating film, the electrode plugs being electrically connected with the gate, source, and drain regions of the N-type and P-type MIS transistors.

10. The manufacturing method of a semiconductor device according to claim 6, wherein,
when nitrogen molecular ions are implanted to the region where the N-type MIS transistor is formed of the semiconductor substrate in the step (e), an implantation dose of the nitrogen ions is in a range of 1×10¹⁵ to 3×10¹⁵ (ions/cm²), and,
when argon ions are implanted to the region where the P-type MIS transistor is formed of the semiconductor substrate is formed in the step (f), an implantation dose of the argon ions is in a range of 0.5×10¹⁵ to 1.5×10¹⁵ (ions/cm²).

11. The manufacturing method of a semiconductor device according to claim 6, wherein
arsenic ions are implanted as the N-type impurity with an implantation dose in a range of 5×10¹⁴ to 3×10¹⁵ (ions/cm²) in the step (e), and
boron ions are implanted as the P-type impurity with an implantation dose in a range of 5×10¹⁴ to 3×10¹⁵ (ions/cm²) in the step of (f).

12. The manufacturing method of a semiconductor device according to claim 6, wherein
a SiGe (silicon germanium) layer is formed on the main surface of the semiconductor substrate before the step (a), and an epitaxial layer containing Si (silicon) is formed on the SiGe layer.

13. The manufacturing method of a semiconductor device according to claim 6, wherein
an SOI (silicon-on-insulator) structure is formed to the semiconductor substrate.
